(19) United States
(12) Patent Application Publication
(10) Pub. No.: US 2005/0273685 A1
(43) Pub. Date: Dec. 8, 2005

(54) Automated and customizable generation of efficient test programs for multiple electrical test equipment platforms

(76) Inventors: Sanjay Sachdev, Hillsboro, OR (US); Charles H. Winstead, Portland, OR (US)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 10/863,084

(22) Filed: Jun. 8, 2004

(51) Int. Cl. G01R 31/28; G06F 11/00

(52) U.S. Cl. 714/742

(57) ABSTRACT

Automating techniques provide a way to create efficient test programs for characterizing semiconductor devices, such as those on a silicon die sample. Typically, test program creation is a drawn out process involving data entry for every test to be run as part of the test program. The described techniques improve test algorithm selection and automatically populate the test algorithm data in creating the test program. The automatic population may occur by accessing test structure, header, and test algorithm catalogs. The test structure catalog contains physical data for the test program, while the header catalog contains global parameter values. The test algorithm catalog has all of the various test algorithms that may be run in a given test, where these test algorithms may be in a template form and specific to any number of different test language abstractions. After test program creation, a validation process is executed to determine if the test program data is valid. Invalid data may be flagged, in an example. Once validated, techniques are described for converting the validated test program into an executable form, by formatting the various test algorithm data in the test program into a form compatible with the applicable test language abstraction selected by the user or the tester.

### FIELD OF THE INVENTION

The present disclosure relates generally to semiconductor circuit testing and, more specifically, to creating efficient testing procedures that may be used by different testing equipment.

### BACKGROUND OF RELATED ART

Microprocessor manufacturers are continually developing and testing new circuit designs, primarily to meet the market's desire for smaller, faster, and more powerful microprocessors. Yet, before creating a new microprocessor, manufacturers must first figure out ways of creating smaller transistors, capacitors, inductors, fuses, ring oscillators, etc., i.e., the constituent circuit elements that form today's microprocessors. As a result, manufacturers view semiconductor device testing as invaluable to all phases of product development, from research and development to final product validation.

In the research and development phase, a manufacturer may spend months designing, building, and testing new layouts and manufacturing processes for constituent circuit elements. A developer may, for example, propose hundreds of different transistor layouts, each varying in size, shape and position from another. A developer may also vary the process used to manufacture the constituent circuit elements, conducting thousands of experiments that vary processing parameters, such as dopant concentration, chemical compositions, implant energy, and other physical manufacturing parameters. A batch of these varying layouts will be fabricated and then tested to determine an optimum design. This research and development phase testing must be thorough, or a manufacturer runs the risk of introducing a faulty or inefficient device into the marketplace.

Typically, different test equipment configurations are used during this product development, as different constituent (semiconductor) devices are being tested. Transistor testing may be very different from ring oscillator testing or capacitor testing, for example, as each device will have different electrode contacts and different characteristics to be tested. Thus, for each different semiconductor device, different test probe configurations may be used and different functions (e.g., applying a voltage in one test and measuring a resistance in another) may be performed. As the number of different semiconductor devices being tested increases, the variations in test equipment configurations changes dramatically.

Not only may semiconductor tests differ between devices, even when testing a single type of semiconductor device different tests may be used. Pin voltages may differ between tests. Or, different tests may be required to measure different metrics. For a single device, different tests may be required to test switching time, switching voltages, resistance, capacitance, stand-by current, power consumption, performance degradation over time, and environment effect, for example. The tests may also vary depending on whether the sample tested is formed on an 8 inch wafer or a 12 inch wafer.

Although testing is important, thorough testing is time consuming and prolongs the product development cycle. It takes a long time to generate test protocols and to train technicians on how to program and implement those test protocols. Generating and implementing thorough tests for a new microprocessor will take months depending on the number of technicians involved.

To electronically test semiconductor devices, it is necessary for users to program the desired tests into the test equipment. The programming process is complicated by the fact that for different test equipment and for different tests, different instructions may be required. Two popular test languages or abstractions are Rocky Mountain Basic (RMB) and HP SPECS (SPECS), both developed by Hewlett-Packard of Palo Alto, Calif. Test designers must know these abstractions and be able to write test programs accordingly. This requires entry of hundreds of data fields by the programmers and technicians. Technicians must have substantial competency with these abstractions to generate common tests.

Of course, it is not surprising that the differences in tests, test equipment, and testing languages leads to testing errors, and potential product roll-out delays.

Due to the enormity of test variables, and the test equipment or test language dependence of these variables, programmers are more likely to err in programming test parameters. Currently, test programmers must know the different test language abstractions and be able to set up test programs that comply with the data structures of these languages. Programmers must access different data stores for specific information for a particular test and a test language abstraction, and then the programmers must be able to manually construct code that may be executed on test equipment, once the technicians have entered the specific test data. The process is very time consuming and potentially fraught with error, if rushed.

As a result of this manual test programming and data entry, testing programs are inefficient and may even produce completely useless data in extreme examples. Programmers and technicians are simply more likely to input incorrect data if that data is test-, test equipment-, or test language-dependent, which semiconductor testing data invariably is. And not only has manual data entry plagued semiconductor testing at the front end, error correction thus far has only been achieved manually, at the back end. In fact, despite the error-prone nature of data entry, no automated techniques for validating test programs exist.

### BRIEF DESCRIPTION OF THE DRAWINGS

FIG. 1 illustrates an example electronic test apparatus, showing a computer system coupled to a semiconductor sample tester.

FIG. 2 details an example implementation of a computer system of FIG. 1.

FIG. 3 illustrates a process for creating and validating a test package and forming an executable test program from the test package, as may be executed with the test apparatus of FIG. 1.

FIG. 4 illustrates an example architecture for the process of FIG. 3.

FIG. 5 illustrates an example of the test package creation process of FIG. 3.

FIG. 6 illustrates a detailed example of a selection routine of the process of FIG. 5.

FIG. 7 illustrates an example test package, before the test package has been fully populated.

FIG. 8 illustrates an example header catalog that may be used in populating the test package of FIG. 7.

FIG. 9 illustrates an example of the test package of FIG. 7 after population by the process of FIG. 5.

FIG. 10 illustrates an example of a test structure catalog accessible by the process of FIG. 5 and that may be used in populating the test package of FIG. 7.

FIG. 11 illustrates an example of the test package validation process of FIG. 3.

FIG. 12 illustrates a detailed example of a validation routine of the process of FIG. 11.

FIG. 13 illustrates an example validation catalog that may be accessed by the processes of FIGS. 11 and 12.

FIGS. 14a and 14b illustrate detailed routines for determining the validity of parameters of the test package of FIG. 9.

FIG. 15 illustrates an example of the test program creation process of FIG. 3.

FIG. 16 illustrates an example tester language template that may be accessed by the process of FIG. 15.

### DETAILED DESCRIPTION

Numerous techniques are described for creating efficient semiconductor device test programs that may be used on multiple electrical tester equipment platforms. The techniques allow users to select various test algorithms, in the form of a number of test templates, to be run on a sample. Once a user selects a number of test algorithms, the techniques may automatically create an entire test package of these test algorithms, whether these algorithms are specific to one type of test language abstraction or another. With some of the disclosed techniques, the amount of time to create the test package may be greatly reduced. This is true whether a technique automatically populates all of the data for a test package or just a portion of the data. Errors in test package creation are also reduced.

Techniques are able to generate code for different tester equipment and test algorithms without having to change the test package format or definitions.

In some of the examples described, validation techniques are implemented that protect against incorrect data entry into the test package. For example, although validation may occur, to an extent, during automatic population of validated data into the test package, a separate validation may be executed, by automatically comparing the populated data with a rules database. A user can create or alter this rules database.

Although techniques are described in somewhat specific examples below, persons of ordinary skill in the art will appreciate that these techniques may be implemented in other testing environments and for devices other than semiconductor based devices. Further, some of the techniques are described with reference to processes that may be implemented by software routines executable on a computer system. The software routines are described with reference to blocks. Persons of ordinary skill in the art will appreciate that the order and method of execution of these software routines is by way of example and that the techniques covered herein are not limited to those shown.

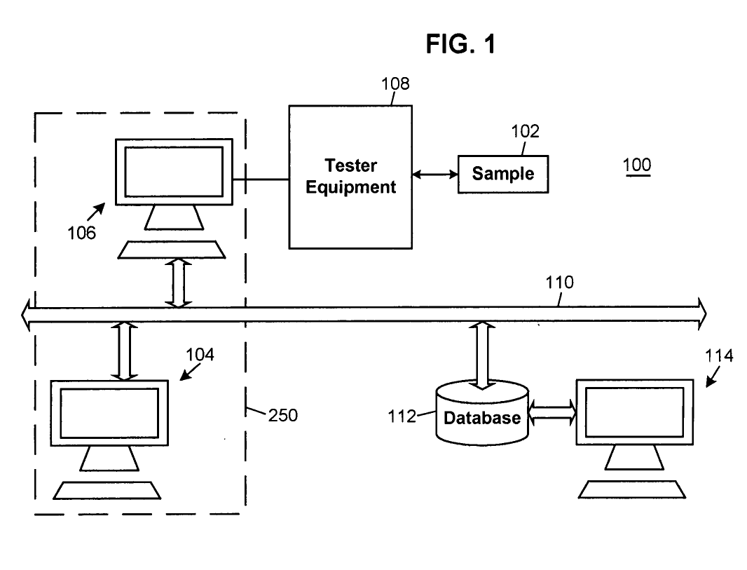

FIG. 1 illustrates an example system 100 for testing a sample 102, such as an 8 inch or 12 inch wafer containing multiple semiconductor structures. The structures may be variations of a single semiconductor device or a number of entirely different semiconductor devices. Example structures include constituent circuit elements like transistors, capacitors, inductors, resistors, and ring oscillators that may be fabricated on a silicon die. Such elements would be typically tested during a technology development stage of a microprocessor roll-out, for example. The sample 102 more generally represents any silicon-based circuit, including integrated circuits as well as microprocessors. Thus, the system 100 may be used in a high-volume manufacturing (HVM) stage, as well.

In the illustrated example, the system 100 includes a first computer station 104 operated by a programmer or technician and coupled to a second computer station 106 that controls tester equipment 108. The stations 104 and 106 may be connected directly or via a computer network 110, wired (as shown) or wireless. The stations 104 and 106 would include display devices and input devices, i.e., keyboard, mouse, etc. In the illustrated example, the computer station 104 may be used by a technician to create test package code that is sent to the computer station 106, which in turn executes the code to run the generated test package on the tester 108.

The tester 108 may be stand alone, table mountable, or portable. Persons of ordinary skill in the art will appreciate that the tester 108 may represent any of the test equipment used in semiconductor device testing, such as ultra-low ammeters, ohmmeters, voltmeters, frequency meters, and capacitance meters. The tester 108 may include built in modules for testing different characteristics of the semiconductor devices on the sample 102. Although an individual tester 108 is shown, the tester 108 may alternatively represent multiple testers or a network of different testers in communication with the computer station 106, or the computer station 104. Furthermore, the tester 108 may operate under any test programming language abstraction, of which RMB or SPECS are examples. The tester 108 may be able to execute code written under different test language abstractions, as well.

The tester 108 may be coupled to test the sample 102 using known coupling techniques. In the illustrated example, the tester 108 has connectors that are coupled to contact pads (or pins) on the sample 102. The contact pads may connect with test structures (i.e., test devices) within the sample 102 or with scribe lines formed on the sample 102 prior to dicing. The connections may contact sub-transistor components, transistor components, via connections, or metal interconnects within the semiconductor sample 102.

The network 110 is coupled to mass storage database 112, which may be accessible to all equipment of the system 100. For example, test data from the tester 108 may be stored in the database 112. The computer stations 104 and 106 may also access the storage database 112 on the network 110, for storing, swapping, or retrieve data. Remote users may analyze tester data via a computer station 114 coupled to the storage database 112. The configuration in FIG. 1 is, of course, an example.

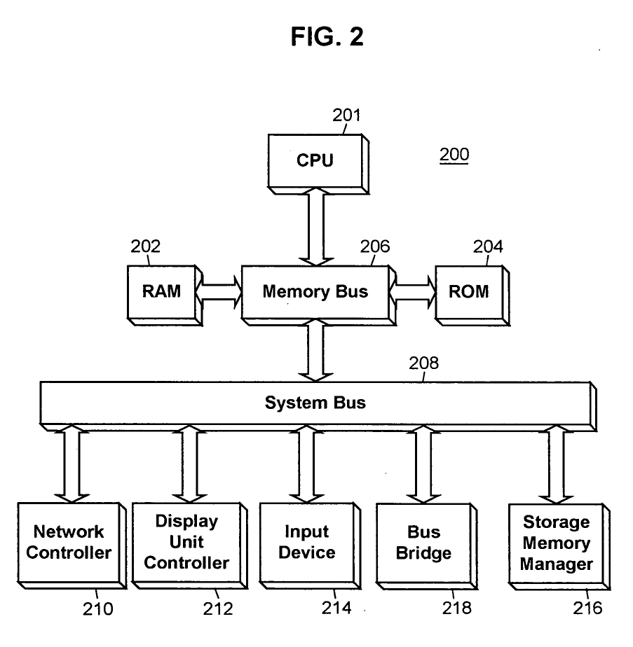

FIG. 2 illustrates an example detailed illustration of a computer architecture 200 for either of the computer stations 104 or 106. The architecture 200 includes a CPU unit 201 coupled to a RAM 202 and a read-only memory (ROM) 204, via a memory bus 206 or CPU bus. In the illustrated example, the memory bus 206 is coupled to a system bus 208. Alternatively, the memory bus 206 may be a system bus. The CPU 201 may include a discrete arithmetic logic unit (ALU), registers, and control unit connected together. Or, as shown, the CPU 201 may be an integrated microprocessor. Persons of ordinary skill in the art will appreciate that the illustrated configuration is an example.

The system bus 208 is coupled to a network controller 210, a display unit controller 212, an input device 214, and a storage memory manager 216, e.g., a mass storage device and interface. Examples of the various devices coupled to the bus 208 will be known. In the illustrated example, the bus 208 may be coupled to another bus via a bus bridge 218.

The operating system operating within the computer stations 104 and 106 may be one of a variety of systems, for example, one of the WINDOWS family of systems available from Microsoft Corporation of Redmond, Wash., such as WINDOWS 95, 98, 2000, ME, CE or XP, including .NET enabled operating systems. Alternatively, the operating system may be one of the UNIX* family of systems, originally developed by Bell Labs (now Lucent Technologies Inc./Bell Labs Innovations) of Murray Hill, N.J. and available from various sources. As a further alternative, the operating system may be an open-source system, such as the LINUX operating system. It will be recognized that still further alternative operating systems may be used.

Various processes that may be implemented by either or both of the computer stations 104 and 106 will now be described. Although, FIG. 1 shows these stations as separate, they will be collectively referenced as computer system 250 to emphasize that either of the stations 104 or 106 may execute any of the processes now described and to emphasize that the stations 104 and 106 may, in fact, be replaced with a single computer system interfacing with a user and the tester 108.

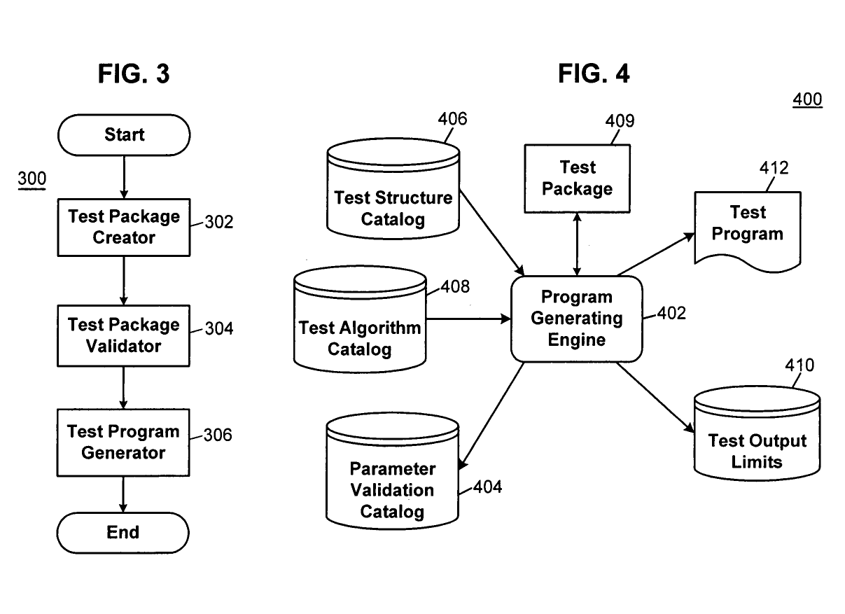

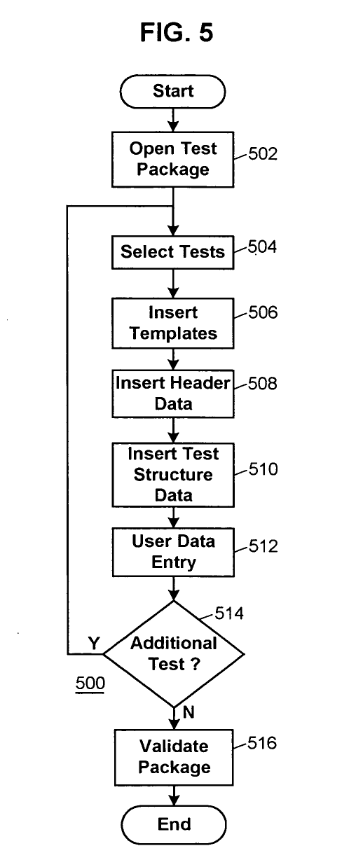

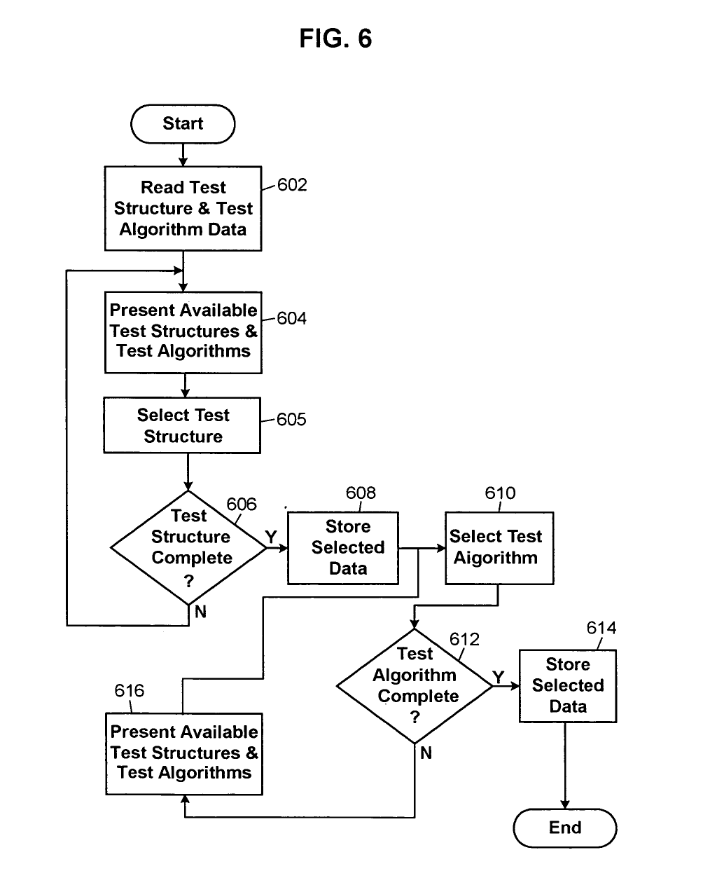

The computer system 250 may execute a process 300 (FIG. 3) to create a test package (i.e., test program) for test characterization of the performance of the sample 102. Three different phases of semiconductor device test formation are shown. A test package creation block 302 executes code on the system 250 that provides the user with an ability to formulate a unique test package from a plurality of different test algorithms by selecting from among available algorithms, regardless of whether those algorithms are test structure-, tester-, or language-specific. The block 302, for example, may access a test algorithms catalog and display the available test algorithms to a user, who then chooses the test algorithms that will form the test package. The process 302 may then populate the test package with validated test data. As explained in further detail with respect to FIGS. 5 and 6, the block 302 may automatically populate the test package with data from a previously header catalog or test structure catalog, for example. Separately, the block 302 may execute programming to allow a user to automatically populate test package data.

At this stage, this test package may be considered incomplete, because it may contain undesirable, invalid data. Even the populated “validated” data from the header catalog, test structure catalog, and test algorithm catalog may, in fact, not be valid for the overall test package being created. Once the test package data has been populated, a block 304 automatically validates the test package data, for example, by comparing the test package data to a rules database stored in a parameter validation catalog. To test validity, the test package validation block 304 may compare the test package data to formatting rules, size limits rules, connection rules, and others. If the data in the test package is invalid, then this may be an indication that the test program is inaccurate, and the block 304 warns the operator of the invalidities.

To generate the code for execution on the tester 108, after test package validation, the validation block 304 is coupled to a test code generation block 306 that creates a validated, executable test program file to be run by the tester 108 in the specific language abstraction used by the tester 108.

FIG. 4 illustrates an example system architecture 400 formed of a test program generating engine 402 that accesses data stored in the system 100. By way of example, the engine 402 accesses a parameter validation catalog 404, a test structure catalog 406, and a test algorithm catalog 408.

As explained in greater detail by example below, the parameter validation catalog 404 may include data rules for the test package data. These rules may be used by block 304 during test package validation.

The test structures catalog 406 includes categorized data that identifies physical characteristics of a semiconductor device, such as the type of device, what part of the device the pins on the sample are connected to, and the dimensions of the device. The test structure data in the catalog 406 may include physical characteristics of a constituent element of a circuit of constituent elements. Furthermore, the catalog 406 may store multiple test structures, one for each device.

The test algorithm catalogs 408 stores the available test algorithms (in template form) that may be executed by the system 100. Test algorithms will vary depending on the test to be performed, but generally, the test algorithms identify (e.g., in template form) the data that is to be provided to tester 108 in executing a test on the sample 102. Test algorithms may include, for example, fields for storing the voltages or currents to be applied to or measured at each of the pins identified in a test structure, as well as variables that are to be used to interpret tester data.

The catalogs 404, 406, and 408 are described as having validated data, i.e., data that has been previously determined or stored as acceptable for a given device or test to be executed on the device. The validation may be from automatically populating the catalogs 404, 406, and 408 from data stores, from automatically deriving data, or from user input. Although the data has been validated for some purpose or according to some prior standards, that validated data may nevertheless not be valid for the particular test package to be formed. For example, a user may execute a test package that contains normally invalid data to test a particular device characteristic.

By way of example, the catalogs 404, 406, and 408 may be preset, e.g., preset based on the testers to be used or the test structure(s), or device(s), to be tested. The catalogs 404, 406, and 408 may store data on all available validation, test structure and test algorithm data, respectively. Or they may store a subset thereof. Alternatively, as the architecture 400 is customizable, users may set the validation, test structure, and test algorithm data stored in the catalogs 404, 406 and 408, respectively. These data may be based on preset data or may be entirely new. If the catalogs 404, 406 and 408 are stored in a writable memory, and not for example hardwired into a test system, then catalog data may be changed without the need for an equipment change or modification. Whether from user customizability or from automatic optimization under the control of engine 402, the data in catalogs 404, 406 and 408 may be modified prior to, during, or after testing.

The catalogs 404, 406, and 408 may be stored on the computer system 250 in a volatile memory, non-volatile memory, RAM, hard disk, optical disk, tape drive or the like. The catalogs 404, 406, and 408 may alternatively be stored, in whole or in part, in a remotely accessible memory storage connected to the network 110. The catalogs may be in a spreadsheet format, such as format compatible with EXCEL, available from Microsoft Corporation, Redmond, Wash. Catalog data may be stored in a relational format that allows the engine 402 to selectively access tables and specific data fields within those tables. Although each of the catalogs 404 408 is described as a single catalog, each in fact may represent multiple catalogs or each may be stored in a single catalog.

The program generating engine may be an executable software routine or group of routines written in a programming language executable on the computer system 200, of which the family of Visual Basic programming languages, available from Microsoft Corporation of Redmond, Wash., is an example.

The program generating engine 402 executes the processes of blocks 302, 304, and 306 of FIG. 3. To track the range of allowable parameter data values, the engine 402 creates an optional test output limits data file 410 from the catalogs 404, 406, and 408. The limits data file 410 may store historical records of the testing conditions and valid data ranges that were effective during the collection of the data by the tester 108. The data may be uploaded to the storage database 112 for analysis. The final, validated test package 409 is converted to an executable test program file 412.

### Test Package Creation

FIG. 5 illustrates a detailed example of an executable process 500 that may be executed as the block 302. A block 502 opens a test package, wherein all the test algorithms and associated data for running a test on the sample 102 may be stored. The block 502 may create a new test package or open an existing one.

To provide a test package identification and any global parameters that may be used throughout the various test algorithms, the block 502 may further open a header catalog and test structure catalog containing such information.

A block 504 executes code to identify test algorithms and test structures available for selection and presents that information to a user. The user selected information may be populated into the test package, in a template format, via a block 506. The templates may be formatted for testing under different test language abstractions, such as RMB or SPECS. The templates contain accessible data fields. Once test templates have been placed into the test packages, the process 500 then begins to populate these data fields with parameters from a first (header) catalog, via block 508, and a second (test structure) catalog, via block 510. A user may enter the remaining parameter data via block 512. The blocks 508 and 510, for example, may search catalogs for parameter values that correspond to data fields in the templates of the test package.

In the illustrated example, the blocks 504-512 are executed for a particular test structure and algorithm selected at block 504. If block 514 determines that a user desires to select an additional test, the process then returns to block 504, allowing the user to select another test structure and/or algorithm. This order is by way of example only, however. Any number of test structures and algorithms may be selected at block 504 before the corresponding data is populated into the test package at blocks 506-512, for example.

The process 500 includes a validation block 516 that may be executed after all the data has been entered for the selected test structures and algorithms, as shown. Or, alternatively, the validation block 516 may be executed on the data entered by blocks 506-512, for each test structure and algorithm on a selection-by-selection basis, for example, with block 516 executing before block 514. Although described in more detail below, the validation block 516 may be similar to the validation block 304 described above.

FIG. 6 shows an example process 600 of the selection block 504. The process 600 identifies available test algorithms to a user, whether those algorithms are for specific tester equipment or specific test language abstraction. The process 600 allows the user to select the test algorithms that are to be executed on the sample. With the process 600, a user may select numerous different test algorithms for compilation into a single test package.

Block 602 accesses the test structure catalog 406 and the test algorithm catalog 408, which each may represent multiple catalogs stored within the system 100. A menu of the available test structures and test algorithms from these catalogs is presented to a user by block 604. The user selects one of the available test structures at a block 605. Then a block 606 determines if test structure selection is complete. If selection is not completed, the process 600 returns to block 604. If test structure selection is complete, block 606 passes control to a block 608, which stores an identification of the selected test structures. Block 608 then passes control to block 610 for selection of the test algorithm. Block 612 determines if the test algorithm selection is complete. If yes, block 612, passes control to block 614 that stores an identification of the test algorithms selected. If no, block 612 passes control to block 616 which presents the user with a list of available test structures and algorithms and returns control to block 610. The user may select to end the selection process at any point during the process 600. And, in other examples, the user may select either a test structure or test algorithm at any point in the process 600 after block 602. The process 600 passes the selection data, stored by blocks 608 and 614, to block 506 for insertion of the test algorithm (template) and test structure data into that algorithm. The blocks of process 600 may be implemented using graphical user interface (GUI), for example in a drop-down menu format.

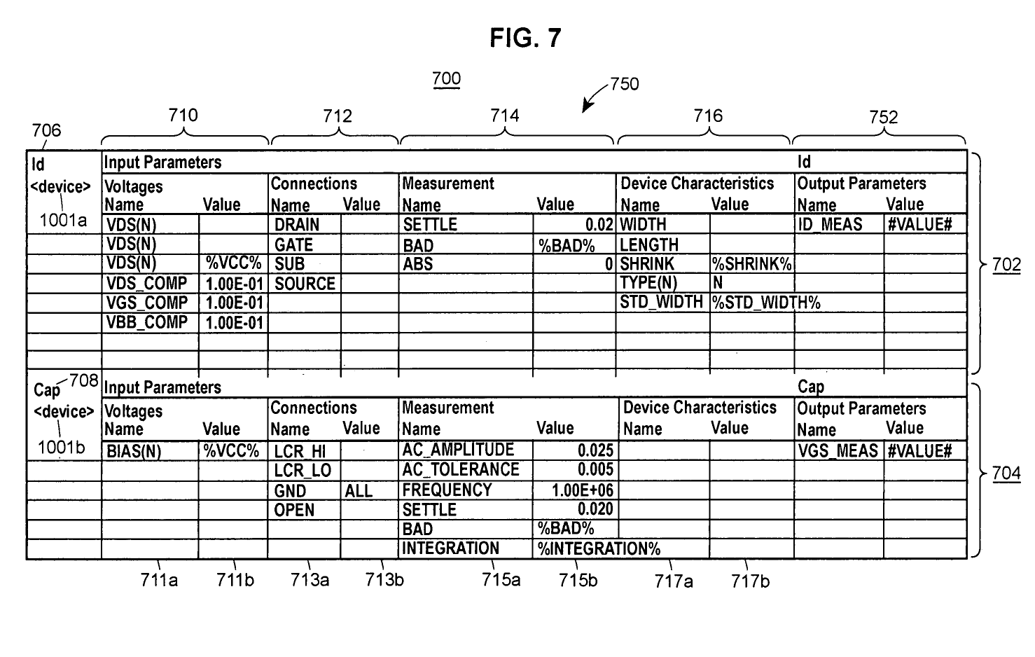

An example of the execution of block 506 will now be described in reference to FIGS. 7-9.

FIG. 7 illustrates a partially assembled test package 700, having two test templates 702 and 704, in spreadsheet form, that may have been previously stored in the test structure catalog 406. The first test template 702 has a name 706, “Id”, and may represent a test algorithm to measure drain current on a transistor. The second test template 704 has a name 708, “Cap” and may represent a separate test to measure a capacitance on a transistor.

The test package 700 contains parameter fields (e.g., spreadsheet fields) for storing parameter data values that may be used by the tester 108 to execute a characterization test on the sample 102. The test package 700 includes fields for parameter names, which describe by name a particular stored data value, and parameter values, which store the actual parameter data.

To store voltages to be applied at various pins on the tester 108, both test templates 702 and 704 contain voltage parameter data 710, with parameter names stored in column 711a and parameter values stored in column 711b, as shown. In the illustrated example, the parameter names include VDS(N), VGS(N), and VBB(N) voltages, for the template 702, and compliance voltages VDS_COMP, VGS_COMP, and VBB_COMP for the template 704. The voltage parameters represent transistor voltages. The compliance voltages parameters represent the allowed tolerances on these voltages.

Each template 702 and 704 may also store connection parameter data 712 identifying pins and connectors, with parameter names stored in column 713a (including DRAIN, GATE, SUB, and SOURCE name parameters for template 702) and parameter values stored in column 713b. The parameter values may store the sample pin or tester connector to be connected to a particular pin. For the template 704, wherein a capacitance is tested, LCR_HI, LCR_LO, GND (ground), and OPEN (open circuit) pins are the listed parameter names.

Each template 702 and 704 stores measurement parameter data 714, that may vary with each test algorithm, but generally includes hard-wired data values. In the illustrated example, the measurement data 714 includes parameter names stored in column 715a. For template 702, SETTLE identifies the settling time for pin measurements; BAD identifies a variable that will be stored by the tester 108 upon any bad or erroneous data; and ABS identifies whether tester data is to be stored in absolute values, or whether negative data values are acceptable. Similar data is stored for template 704, which also includes AC_AMPLITUDE and AC_TOLERANCE parameter names, which identify maximum voltages for AC signals, and fluctuation tolerances for that maximum voltage. The FREQUENCY of an AC signal applied by the tester 108 is also identified, along with INTEGRATION, which may represent the quality of a numerical integration algorithm used in computations (low/med/high). These parameters are by way of example and may change depending on the test algorithm. Persons of ordinary skill in the art will recognize that any data useful for a particular semiconductor device test may be stored in any of the data parameters illustrated. That is, any of fields in an existing test algorithm template may be populated into the test package 700. The associated parameter values for the measurement data are stored in column 715b, where the actual hand-wired data values are kept.

Device characteristic parameter data 716 is stored for each of the templates 702 and 704, as well. Similar to the measurement data 714, the device characteristic data 716 may store general data attributable specifically to the device to be tested in the test algorithm. For template 702, WIDTH and LENGTH parameter names are stored in column 717a, with corresponding dimension data stored in the associated parameter values column 717b. SHRINK data is also stored and represents a global scaling factor to be applied to all geometric parameters. TYPE data identifies the type of device tested, e.g., N-type or P-type. STD_WIDTH identifies the nominal target geometry of the device around which the tester may tweak the geometry to find a better configuration. These data, which describe the physical structure of the device to be tested, are by way of example.

The templates 702 and 704 are automatically created in the test package 700 by block 506, which pulls templates for the selected test algorithm from the test algorithm catalog 408. The resulting test package 700, generally, may include three kinds of data as value parameters in columns 711b, 713b, 715b: hard-wired data, blank data, and global data.

Hardwired data are those real numbers that were previously stored in the test algorithm template of catalog 408. Examples of hardwired data values in FIG. 7 include the SETTLE value “0.02,” the VDS_COMP value “1.00E-01,” and the AC_AMPLITUDE value “0.025.” The hardwired data shown are by way of example and do not pertain to any particularly known or contemplated test. Global data are those fields identified by a %<variablename>% tag, and include % VCC %, % BAD %, % INTEGRATION %, % SHRINK %, and % STD_WIDTH %, in the illustrated example. These are just representative examples, however. Any of the data fields may contain global data flags. The remaining fields contain blank data.

The data described thus far in test package 700 is input parameter data 750. The test package 700 may also include output parameter data where characterization data of the sample 102 may be stored. For example, template 702 includes an output parameter data 752 having a parameter name, ID_MEAS, and an associated parameter value for storing a transistor drain current measured by the tester 108. The parameter value may be populated by data obtained from the tester 108 after a test on the sample 102. The output parameter data 752 may also include data measured by a prior test algorithm. Template 704, for example, includes VGS_MEAS data that stores a past measured voltage across the gain and source of a transistor. In other words, output parameter data 752 may store current and past measurement test data. Alternatively still, the output parameter data 752 may store computed data derived from the input parameter data 750. In a further alternative, the output parameter data 752 may include other parameter data, such as the units of the parameter being measured, the name of variable where the measurement will be stored, the name of the database where the measurement will be stored, a scalar to be applied to the measured value, and user generated or automatically generated test description data, for future reference in analyzing the test data.

The process 500 executes code to populate data into a test package. That data may come from various pre-validated catalogs, having data that has already been completed for certain valid tests. In other words the process 500 can self-validate test package creation by populating the test package with data from existing valid catalog data.

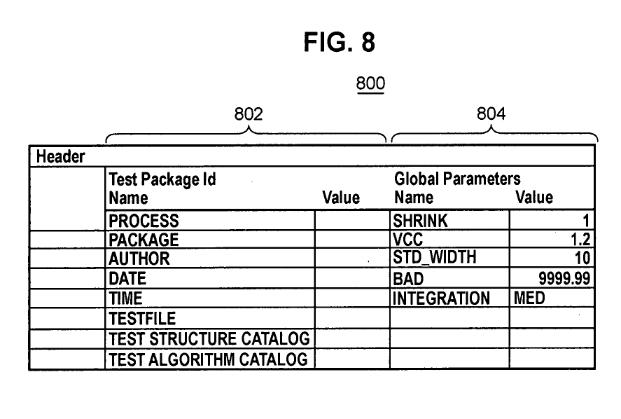

Once the test package 700 has been populated with one or more test templates from the catalog 408, blocks 508 and 510, for example, attempt to fill parameter values of the test package. Specifically, the block 508 links the global data of a test package to a header catalog to see if the header catalog has any corresponding global data stored therein. A sample header catalog 800 is shown in FIG. 8.

The header catalog 800 includes test package ID data 802, with parameter names including PROCESS name, PACKAGE name, AUTHOR of the test, DATE the test was created, and TIME of test creation. The TESTFILE name where the generated tester code is to be stored is also contained within the header catalog 800, along with parameter values identifying a test structure catalog and test algorithm catalog, where test data compatible with the header 800 may be stored.

Any global data, in the illustrated example, is stored as global parameter data 804. As can be see in the illustrated example, the header catalog 800 stores parameter names and values for the following global data: SHRINK, VCC, STD_WIDTH, BAD, and INTEGRATION. The block 508 may search the catalog 800 and find the parameter name matching the global data tag in the test package 700 and populate the associated parameter value from the header 800 into the test package 700.

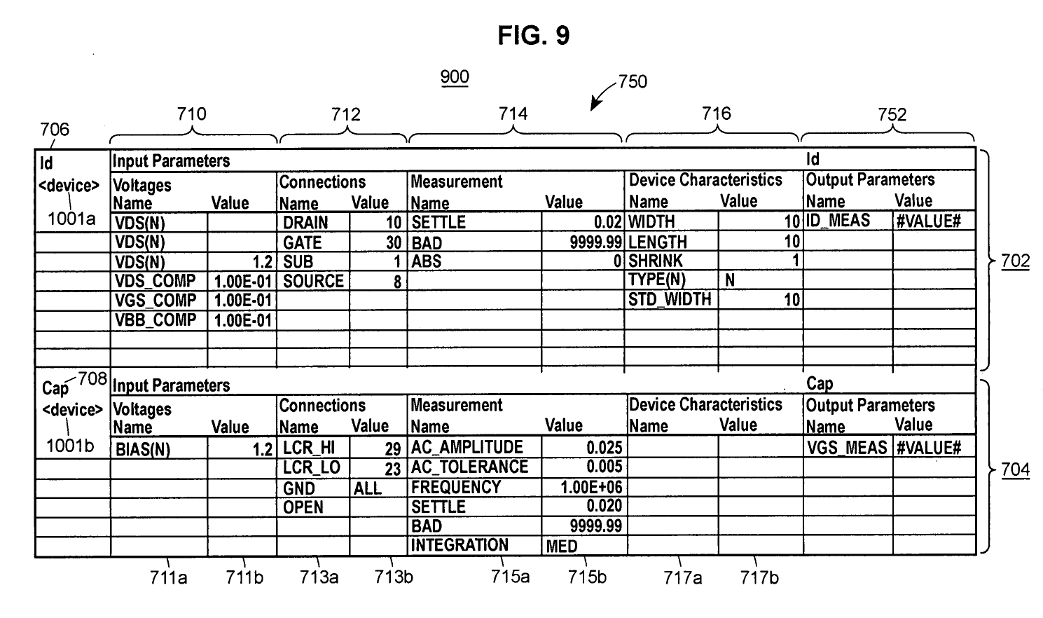

A populated version of the test package 700, after global data values have been populated from the header catalog 800, is shown in FIG. 9, as test package 900 (sharing like reference numbers with test package 700). As can be seen, global data for VCC, BAD, SHRINK, STD_WIDTH, BIAS(n), and INTEGRATION have all been automatically obtained and populated from the header catalog 800, by block 508.

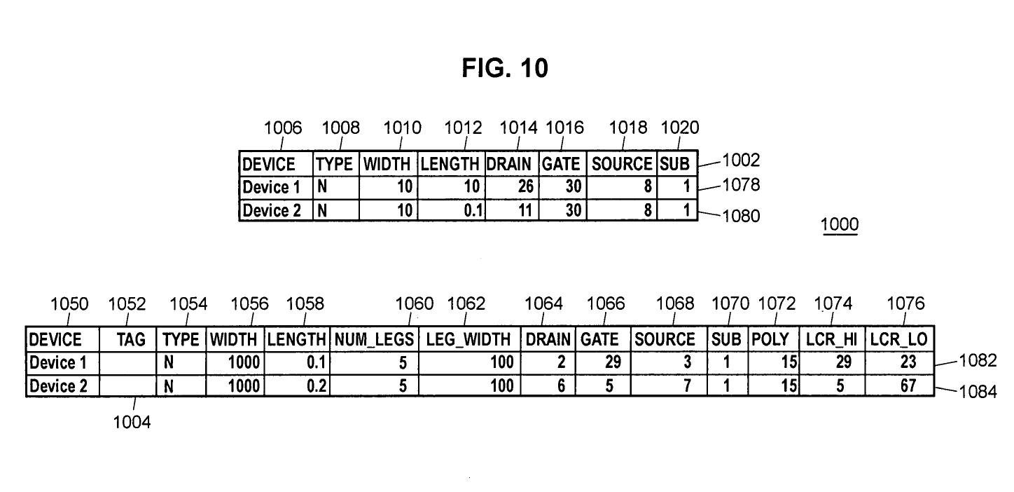

The block 508 searches the header catalog 800 for global data values, but even if all global data values are found in the header catalog, which may or may not occur, the test template 700 may still have blank data values that are to be populated. Toward that end, the block 510 searches the test structure catalog 406 for the data. For example, the block 510 may open a test structure catalog 1000, such as that shown in FIG. 10 and determine if any of the block data fields in the test package 700 have associated values stored in the test structure 1000.

The sample test structure catalog 1000 contains data in two different tables 1002 and 1004, which each represent a different semiconductor device to be tested. In the illustrated example, the test structure 1002 stores physical characteristic data for testing such things as currents for a transistor, while the test structure 1004 stores data for testing such things as transistor capacitance.

The test structure data of the catalog 1000 are stored in columns. The specific columns illustrated are by way of example only. The table 1002 includes a DEVICE column 1006 that may be used to identify different variations of the semiconductor device corresponding to test structure 1002. Other illustrated columns include, TYPE 1008, WIDTH 1010, LENGTH 1012, DRAIN 1014, GATE 1016, SOURCE 1018, and SUB 1020. The TYPE 1008 column may identify the device as N-type or P-type. The WIDTH and LENGTH columns 1010 and 1012 may represent the dimensions of the device being tested. The DRAIN 1014, GATE 1016, SOURCE 1018, and SUB 920 columns represent pin parameter data fields that identify the pins on sample 102 and what they are connected to, which in this example included different parts of a semiconductor transistor element.

The test structure 1004 may contain the same, similar, or different columns, depending on the device testing to be described. For example, the test structure 1004 includes the following columns; DEVICE 1050, TAG 1052, TYPE 1054, WIDTH 1056, LENGTH 1058, NUM_LEGS 1060, LED_WIDTH 1062, DRAIN 1064, GATE 1066, SOURCE 1068, SUB 1070, POLY 1072, LCR_HI 1074, and LCR_LO 1076. For the test structure 1004 used to measure capacitance, NUM_LEGS 1060 is the number of legs (connectors) connected to the device. LEG_WIDTH 1062 is the geometry of these legs. LCR_HI 1074 and LCR_LO 1076 are the connections to the capacitance meter or tester. These columns are by way of example.

Persons of ordinary skill in the art will appreciate that the illustrated test structure catalog 1000, along with the other illustrated catalogs herein, is by way of example only.

Block 510 searches the test structure catalog 1000 for any of the data values to be populated in the test package 700. The block 510 may look for any blank data fields in the test package 700 and automatically populate corresponding data from the test structure catalog 1000 into those fields. Corresponding data may be identified by comparing the column name in the catalog 1000 with the parameter name of the test package 700. The catalog 1000 contains data for different devices 1078, 1080, 1082, and 1084, two for each table 1002 and 1004. The block 510 populates data from the catalog 1000 that corresponds to the particular device being tested by the particular test algorithm. The device for a given test algorithm, as stored at block 608, may be identified in the templates 702 and 704 via a device place holder 1001a and 1001b.

For the test template 900, the block 510 has populated the LCR_HI and LCR_LO parameter values with “29” and “23,” respectively, from the device 1082 of the table 1004. The pin parameter values for DRAIN, GATE, SUB, and SOURCE have also been populated from the test structure 1000, in this example device 1078 of the table 1002—the identified pins being “26”, “30”, “1”, and “8,” respectively. WIDTH and LENGTH data values were also populated from the table 1002, device 1078, and stored in the test template 900.

In addition to automatically populating data from the test structure catalog 1000 into the blank data fields of the test package 700, the block 510 may also search for data to populate into fields that already contain data, such as previously populated or unpopulated global data values or hardwired data values. That is, the block 510 may search the test structure catalog 1000 for data to populate into any parameter value fields of the test package 700, even if the blocks 508 or 506 have previously populated that field. Alternatively, the block 510 may be executed to give priority to the previously populated value in a field and not over-write that field with data from the test structure catalog 1000.

### Test Package Validation

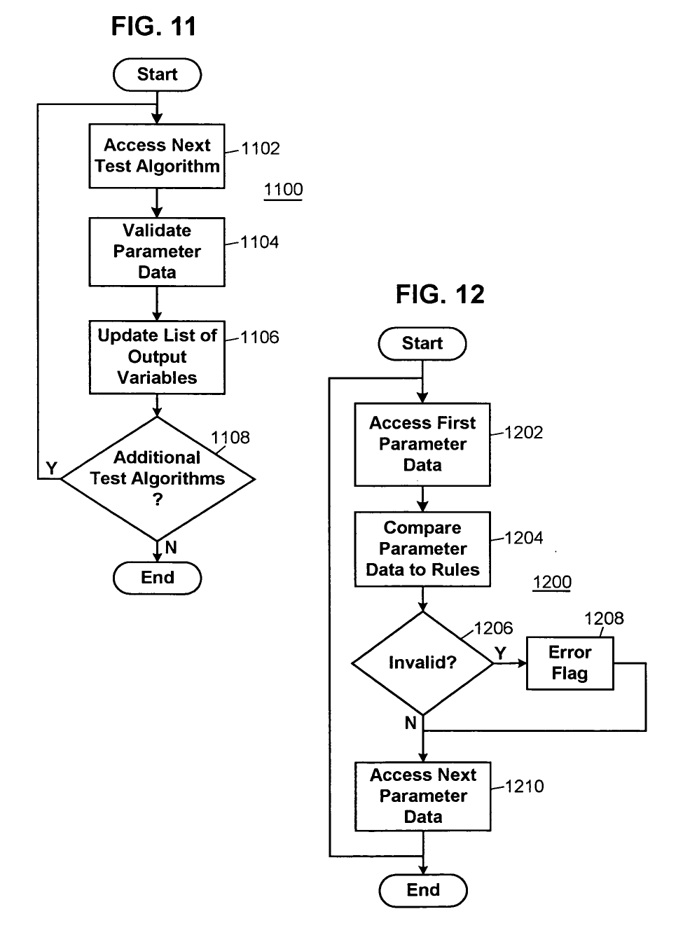

The process 302 is used to create a test package, however, a user may enter incorrect data into a test algorithm at block 512. To identify errors to a user, the test package validation block 304 executes code to determine if the test package created at the block 302 is valid given a set of existing or subsequently determined parameters. A general example of the process 304 is shown in FIG. 11.

A first block 1102 accesses the first test template of the test package 900, which in the illustrated example would be test template 702. Block 1104 validates the parameter data in this first test template, which as will be explained in further detail below includes validating both input parameters and output parameters. After validation, a block 1106 adds a list of the output parameter variables to a working database. Then a block 1108 determines if there are any additional test templates in the test package. If additional test templates exist, control is returned to block 1102. Otherwise the process 1100 ends. The validation programming executed by block 1104 is described in further detail in reference to FIGS. 12, 13, 14a and 14b.

FIG. 12 illustrates a detailed example of validating the input parameters of a test package, such as the input parameters 750. The process 1200 includes a first block 1202 that accesses a first parameter in the test template being validated. A block 1204 compares the parameter data to a rules database. For example, the block 1204 accesses the parameter validation catalog 404 and compares the parameter data to the rules of the catalog 404. A block 1206 determines if the parameter data satisfies the rules criteria or not. If the data value does not, then a block 1208 flags the parameter data fields (both the parameter name and the parameter value). In an alternative example, the block 1208 may also provide a comment instructing a user with information on the reason for the flag. If the parameter value checked by block 1204 does satisfy the rules criteria, than the block 1206 passes control to a block 1210 which determines if additional parameter data exists within the template being tested.

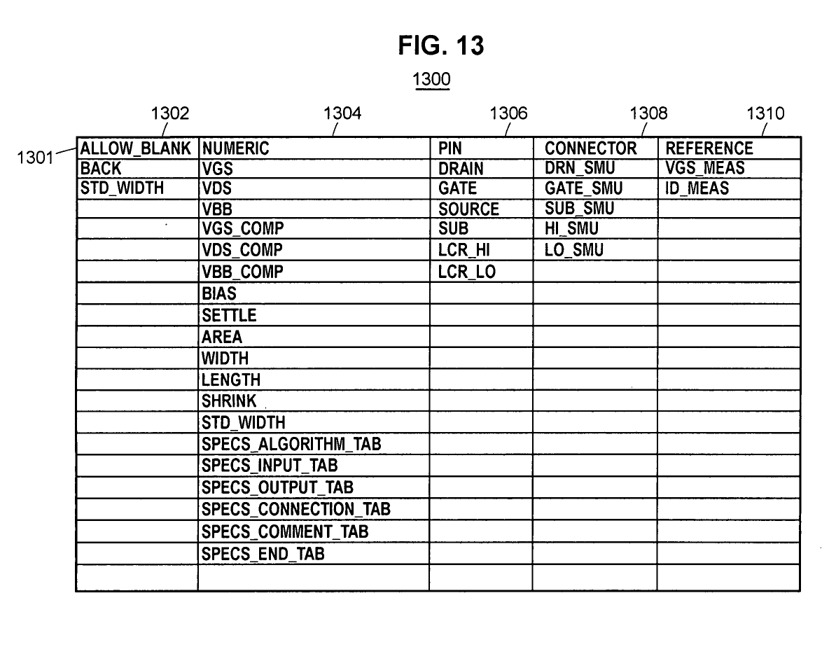

An example of the parameter validation catalog 404 is illustrated in FIG. 13 as table 1300.

The catalog 1300 includes various columns that define permissions for the parameter names identified therein. The catalog 1300 includes a header row 1301 that identifies each column. For example, a first column 1302 identifies those parameter values that may be left blank in the test package 900. BACK and STD_WIDTH are the only two identified. A second column 1304 identifies those parameter names that are to have a numerical value stored as the associated parameter value. A third column 1306 identifies the various pin parameter names that are to include a valid pin parameter value. A fourth column 1308 identifies the specific tester equipment connector parameter names that are to include a valid connector parameter value.

Column 1310 is used to identify suitable output parameter names. The column 1310 may store a list of valid variable names that may appear in the output parameter section of the test package 900. This is used for test packages that make multiple measurements and rely upon past measurements for future test algorithms. The column 1310 identifies those variables that are available for use in the current test template, because the particular value should exist in the output parameter section of a previous test to ensure that the value has been measured before it is used in a new test. The identified parameter names are by way of example.

The parameter validation catalog 1300 of FIG. 13 is shown by way of example only. Additional, fewer, or other columns may be provided in this rules catalog 1300. For example, new definitions of rule types may be added. Furthermore, it will be understand to persons of ordinary skill in the art that parameters may appear in more than one column, where parameters are to satisfy multiple rules. Further still, many parameters may be absent from the catalog 1300, altogether.

The catalog 1300 may be created from pre-determined or previously-accessed data, tester equipment, a test structure, a test algorithm catalog, or other stored data. The catalog 1300 may be created or altered by a user, as well. The catalog may be created or modified during the process 300.

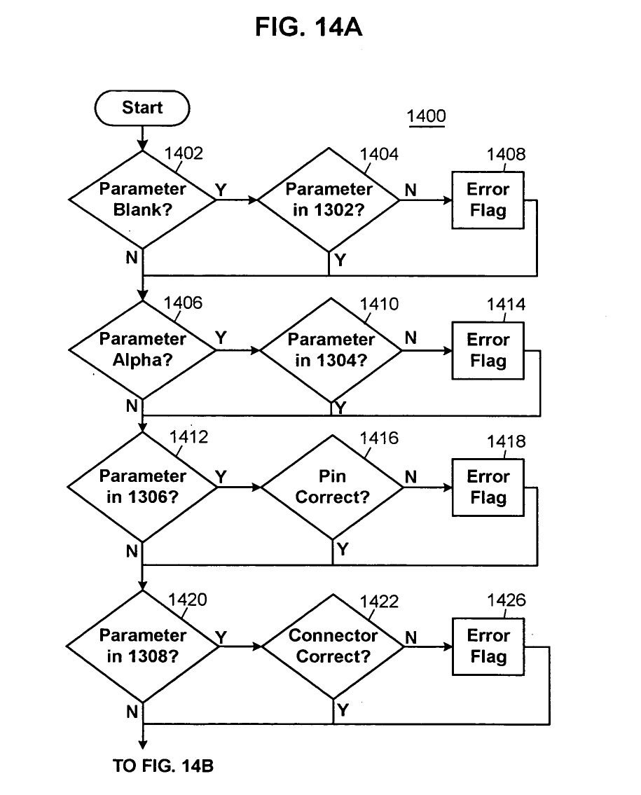

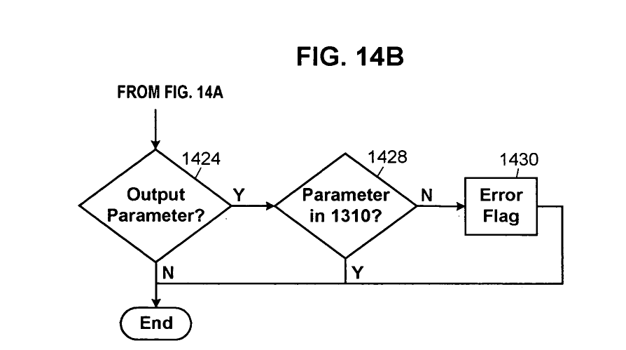

FIG. 14a illustrates an example process 1400 that may be executed by block 1204 to check the validity of an input parameter data. Specifically, block 1402 determines if the parameter value is blank and if it is, a block 1404 searches column 1302 to determine if the parameter name for that parameter value is included. If it is included, control passes to a block 1406. If it is not, an error flag is displayed by a block 1408 and control passes to block 1406.

The block 1406 determines whether the parameter value is alphanumeric of not. If it is, a block 1410 determines if the parameter name is listed in column 1304. If it is not, then the parameter value is allowed to be alphanumeric by the rules of the parameter validation catalog 1300 and control passes to a block 1412. However, if the parameter name is listed, then the parameter value is not allowed to be alphanumeric and an error flag is displayed by block 1414 before control passes to block 1412.

Block 1412 determines if the parameter name is listed in the pin column 1306. If it is not, then control passes to a block 1416. If the parameter name is listed in column 1306, a block 1416 determines if the pin value stored in the parameter value is a valid pin number, for example, by checking the pin data stored in a test structure catalog. Valid pin values may be hard-coded and accessible by a processor. These valid pin values may be standard across testers. If the stored parameter value is not a legitimate pin number, then an error flag is displayed at block 1418, which passes control to a block 1420. Otherwise, if it is determined that the pin number is valid, then control passes directly to block 1420.

Block 1420 determines if the parameter name is listed in the connector column 1308. If it is, a block 1422 determines if the parameter value is a legitimate connector, for example, by comparing the parameter value to validated connector values that may be hard-coded in a processor accessible memory. By way of example, validated connector values may include SMU0-SMU4, DMH, DML, CMH, and CML, and these values may be standard across testers. Otherwise, the block 1420 passes control to a block 1424, of FIG. 14b. If block 1422 determines that the connected value is not valid, a block 1426 provides an error flag and control is passed to block 1424. If the connector is legitimate, then block 1422 passes control directly to block 1424.

FIG. 14b illustrates a portion of the process 1400 for validating output parameters. A block 1424 determines if the parameter value being tested is an output parameter. If it is not, then the process 1400 ends. If it is, then a block 1428 compares the associated parameter name to column 1310 of the parameter validation catalog 1300, to determine if the parameter name is an allowable parameter name or not. Allowable parameter names may be those representing current or past characterized data tested by the tester 108. If the parameter name does not appear in column 1310, then the parameter name is invalid and an error flag is presented to the user by block 1430. Otherwise, the process ends. Additional output parameters may be validated by different rules.

Any of the above error flags may also include an instruction message displayed to the operator by the computer system 250.

### Test Program Creation

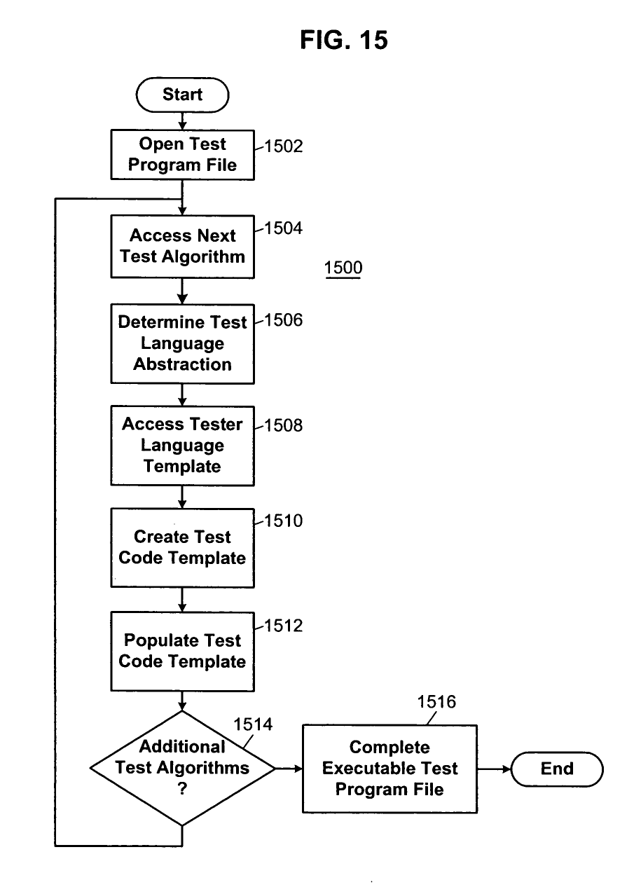

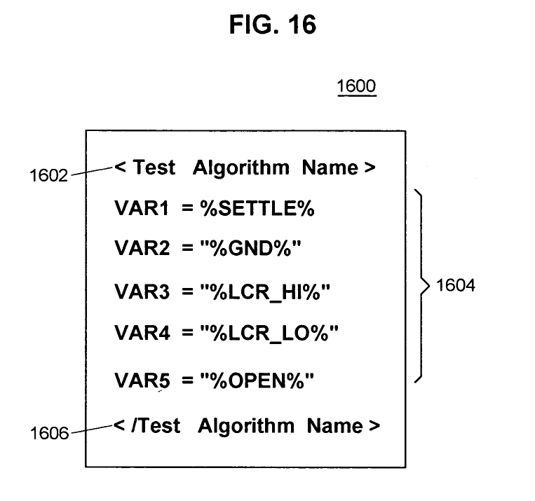

FIG. 15 illustrates an example test program file creation process 1500 that may be executed by block 306 of FIG. 3. With the test package 900 populated and all the errors flagged by block 304, the process 300 may create an executable test program file to be executed on the tester 108. As the test package may contain test algorithms designed for execution in a particular test language abstraction, the process 1500 is able to convert test algorithms into any of a variety of formats. A block 1502 creates a test program file or opens an existing file. A block 1504 accesses a first test algorithm in the test package. A block 1506 determines the test language abstraction associated with that test template, which may be done automatically by accessing test language abstraction information in the test package, test algorithm catalog, or header catalog. Alternatively, a user may determine the test language abstraction to be used to execute the given test algorithm. Or, the test language abstraction may have been determined for all test algorithms by the user's selection of the target platform or tester. A block 1508 then accesses a catalog containing a tester template specific to the test language abstraction. For example, the block 1508 may access a tester template having formatting rules for converting spreadsheet data into a test language abstraction, like RMB or SPECS. The tester template may be stored in a file, such as a header and/or test algorithm catalog, like catalog 700, or it may be stored separately. An example code template is illustrated in FIG. 16.

FIG. 16 illustrates an example tester language template 1600 that may be used to convert test structure and test algorithm data to a format compatible with the test language abstraction. The template 1600 includes a test algorithm delimiter 1602 that identifies a particular code, such as a particular test algorithm that is one of the test algorithms that is to be executed during the test. Below the test algorithm delimiter 1602 is template conversion data 1604 for the test algorithm in test algorithm delimiter 1602. In the illustrated example, the conversion data 1604 includes a plurality of tester language specific variables, VAR1, VAR2, VAR3, and VAR4, and a plurality of test structure or test algorithm values that are to be assigned to these variables by the tester template 1600. In the illustrated example, VAR1 is assigned the value % SETTLE %, VAR2 the value “% GND %”, VAR3 the value “% LCR_HI %”, VAR4 the value “% LCR_LO %”, and VAR5 the value “% OPEN %”, where % denotes a variable and ″ denotes a string variable instead of a numeric variable. The values for these variables are discussed above in reference to FIGS. 7-10. In the illustrated example, when the test program file is created, the conversion rules data 1604 may be used to convert the test algorithm and test structure data to data that is executable under the tester language abstraction. The conversion data ends with another test algorithm delimiter 1606, which indicates the end of the identified test algorithm. Persons of ordinary skill in the art will appreciate that these variables and mappings are examples only and may depend on the rules of the test language abstraction. Furthermore, the conversion data may be procedural or declarative data, as different test language abstractions may use either or both statement forms. Further still, the tester conversion template 1600 may have other forms and may include additional test algorithms.

In reference back to FIG. 15, a block 1510 then creates a test code template in the test program file based on test language abstraction determined by block 1506 and the conversion rules of the tester template of block 1508. A block 1512 populates the test code template with the parameter data from the test package, using any applicable conversions from block 1508. A block 1514 then determines if additional test templates exist within the test package and returns control to block 1502 if they do. Otherwise, a block 1516 completes the test program into an executable format, and the process ends.

Although the block 1508 is described as accessing a tester template, the block 1508 may access any catalog file having test language abstraction format information. Furthermore, the block 1508 may access a different tester template for a subsequent test algorithm, if that algorithm is to be executed in a different test language abstraction than the one used for the first algorithm. Other alternatives will become apparent to persons of ordinary skill in the art.

Although certain apparatus constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalence.

1. A method of forming a test package for analyzing characteristics of a semiconductor sample via an electrical tester machine, the method comprising:
identifying a plurality of test algorithms, each test algorithm defining a semiconductor device test;
populating a test package with the plurality of test algorithms, wherein each test algorithm comprises parameter data fields for populating with validated parameter data values;
searching at least one catalog for the validated parameter data values; and
in response to finding at least one validated parameter data value, populating the at least one validated parameter data value into the test package.

2. The method of claim 1, wherein identifying a plurality of test algorithms comprises accessing a test algorithms catalog.

3. The method of claim 2, wherein at least two of the plurality of test algorithms define different semiconductor device tests.

4. The method of claim 2, wherein the test algorithm comprises connector parameter fields.

5. The method of claim 1, wherein the parameter fields comprise a global data field, and wherein searching the at least one catalog comprises:
searching a header catalog for a first validated global data value corresponding to the global data field.

6. The method of claim 5, further comprising:
searching a test structure catalog for a second validated global data value corresponding to the global data field; and
populating the global data field with the second validated global data value in place of the first validated global data value.

7. The method of claim 1, further comprising validating the test package.

8. The method of claim 7, wherein the test package comprises a plurality of: parameter data values, further comprising:
comparing the plurality of parameter data values to a rules database; and
determining if the plurality of parameter data values satisfy rules of the rules database.

9. The method of claim 8, further comprising flagging any parameter data values that do not satisfy the rules of the rules database.

10. The method of claim 7, wherein the rules database includes at least one pin rule and at least one connector rule.

11. The method of claim 1, wherein the test package comprises voltage parameter data and connection parameter data.

12. The method of claim 1, wherein the test package comprises measurement parameter data and device characteristics parameter data.

13. The method of claim 1, wherein the test package is storable in a spreadsheet format.

14. The method of claim 1, wherein the test package includes at least one parameter field comprising a global data tag.

15. The method of claim 1, further comprising converting the test package to a test program file executable on the tester equipment.

16. The method of claim 15, comprising:
accessing one of the plurality of test algorithms in the test package;
accessing a first test code template; and
populating the first test code template with parameter data from the test algorithm.

17. The method of claim 16, comprising:
accessing another of the plurality of test algorithms in the test package;
accessing a second test code template; and
populating the second test code template with parameter data from the test algorithm.

18. A method of forming a test program for analyzing characteristics of a semiconductor sample via an electrical tester machine, the method comprising:
creating a test package having a plurality of test algorithms, wherein one of the plurality of test algorithms corresponds to a first test code template and wherein at least one other of the plurality of test algorithms corresponds to a second test code template; different than the first test code template;
populating the test package with parameter data values; and
validating the parameter data values.

19. The method of claim 18, further comprising converting the test package to an executable test program file.

20. The method of claim 19, further comprising:
accessing a first test code template;
populating the first code template with parameter data from the one of the plurality of test algorithms;
accessing a second test code template; and
populating the second code template with parameter data from the other of the plurality of test algorithms.

21. The method of claim 18, wherein populating the test package comprises searching a first catalog for validated parameter data values.

22. An article comprising a machine-accessible medium having stored thereon instructions that, when executed by a machine, cause the machine to:
identify a plurality of selected test algorithms, wherein each test algorithm defines a semiconductor device test;
populate a test package with the plurality of selected test algorithms;
search a catalog for validated parameter data values for populating into the test package; and
populating validated parameter data values into the test package.

23. The article of claim 22, having further instructions that, when executed by the machine, cause the machine to access a test algorithms catalog.

24. The article of claim 22, having further instructions that, when executed by the machine, cause the machine to search a catalog for validated global data values for populating into the test package.

25. The article of claim 24, wherein the test package comprise at least one global data field having a global data tag, identifying a global data value to be searched for.

26. The article of claim 22, wherein the test package comprises a plurality of parameter data values, and having further instructions that, when executed by the machine, cause the machine to:
compare the plurality of parameter data values to a rules database; and
determine if the plurality of parameter data values satisfy rules of the rules database.

27. The article of claim 26, having further instructions that, when executed by the machine, cause the machine to flag any parameter data values that do not satisfy the rules of the rules database.

28. The article of claim 22, having further instructions that, when executed by the machine, cause the machine to convert the test package to a test program file executable on a semiconductor test equipment.

29. The article of claim 28, having further instructions that, when executed by the machine, cause the machine to:
access one of the plurality of test algorithms in the test package;
access a first test code template; and
populate the first test code template with parameter data from the test algorithm.

30. The article of claim 29, having further instructions that, when executed by the machine, cause the machine to:
access another of the plurality of test algorithms in the test package;
access a second test code template; and
populate the second test code template with parameter data from the test algorithm.
